(19) United States
(12) Patent Application Publication
(10) Pub. No.: US 2024/0371771 A1
(43) Pub. Date: Nov. 7, 2024

(54) INTERRUPTION LAYER FILL FOR LOW RESISTANCE CONTACTS

(71) Applicant: Applied Materials, Inc., Santa Clara, CA (US)

(72) Inventors: Sahil Jaykumar PATEL, Sunnyvale, CA (US); Wei LEI, Santa Clara, CA (US); Tuerxun AILIHUMAER, Santa Clara, CA (US); Joung Joo LEE, San Jose, CA (US); Rongjun WANG, Dublin, CA (US); Xianmin TANG, San Jose, CA (US)

(21) Appl. No.: 18/423,437

(22) Filed: Jan. 26, 2024

Related U.S. Application Data
(60) Provisional application No. 63/464,041, filed on May 4, 2023.

(51) Int. Cl. H01L 23/532; H01L 21/768

(52) U.S. Cl. CPC H01L 23/53266; H01L 21/76814; H01L 21/76843; H01L 21/76879

(57) ABSTRACT

Embodiments of the disclosure include an apparatus and method of forming a semiconductor structure that includes metal contacts with a low resistance. In some embodiments, the semiconductor device generally includes an interconnect. The interconnect generally includes a dielectric layer with a tungsten (W) plug formed therein, a feature formed in the dielectric layer and over the W plug, a liner layer formed on an exposed surface of the W plug and on sidewalls of the feature, an interruption layer formed on the liner layer, and a conductive material substantially filling the feature. The liner layer includes molybdenum (Mo) or W, and the interruption layer includes Mo.

### CROSS-REFERENCE TO RELATED APPLICATION

This application claims the benefit of and priority to U.S. Provisional Application 63/464,041 filed on May 4, 2023, which is assigned to the assignee hereof and hereby expressly incorporated by reference herein in its entirety as if fully set forth below and for all applicable purposes.

### BACKGROUND

### Field

Embodiments described herein generally relate to semiconductor device fabrication. More specifically, embodiments of the present disclosure relate to semiconductor devices that includes low resistance contacts and methods of forming the same.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. An example of such a device include memory (e.g., DRAM) and logic devices, including both planar and three-dimensional structures. An example of a three-dimensional structure is a finFET or MOSFET devices.

An example of finFET or MOSFET includes a gate electrode on a gate dielectric layer on a surface of a semiconductor substrate. Source/drain regions are provided along opposite sides of the gate electrode. The source and drain regions are generally heavily doped regions of the semiconductor substrate. Usually a silicide layer, for example a titanium silicide layer, is required to form a reliable contact at the formed source and drain regions.

In a traditional middle-end-of-the-line (MEOL) contact formation process, a feature, such as a via or trench is fabricated in the semiconductor substrate. MEOL contact allow connections between front-end-of-the-line (FEOL) semiconductor structures and back-end-of-the-line (BEOL) interconnects. Contacts with low resistance are desirable in semiconductor devices. However, when a MEOL contact has a relatively high resistance, a poor connection is created at the MEOL contact, which reduces the overall performance of the packaged semiconductor structures.

Contacts with low resistance are desirable in semiconductor devices. Both tungsten (W) and molybdenum (Mo) are preferred materials for use as middle-of-line (MOL) and back-end-of-line (BEOL) features (including vias and/or trenches) in semiconductor devices. However, conventional feature fill processes often have very low throughput, negatively impacting tool productivity, and there remain challenges in providing features with low resistance.

Therefore, there is a need in the art for a process that is used to form reliable contact structures and solve the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide a method of filling a feature in a semiconductor structure. The method generally includes forming a liner layer on sidewalls of the feature and an exposed surface of a conductive layer within the feature, the feature being formed in a dielectric layer formed over the conductive layer. The liner layer includes molybdenum (Mo) or tungsten (W). The method also generally includes forming an interruption layer on the liner layer, and substantially filling the feature with a conductive material. The interruption layer includes Mo.

Embodiments provided herein generally include an interconnect formed in a substrate. The interconnect generally includes a dielectric layer with a tungsten (W) plug formed therein, a feature formed in the dielectric layer and over the W plug, a liner layer formed on an exposed surface of the W plug and on sidewalls of the feature, an interruption layer formed on the liner layer, and a conductive material substantially filling the feature. The liner layer includes molybdenum (Mo) or W, and the interruption layer includes Mo.

Embodiments of the present disclosure provide a method of filling a feature in a semiconductor structure. The method generally includes forming an interruption layer on sidewalls of the feature and an exposed surface of a conductive layer within the feature, the feature being formed in a dielectric layer formed over the conductive layer, and substantially filling the feature with a conductive material. The interruption layer includes molybdenum (Mo).

Embodiments provided herein generally include an interconnect formed in a substrate. The interconnect generally includes a dielectric layer with a tungsten (W) plug formed therein, a feature formed in the dielectric layer and over the W plug, an interruption layer formed on an exposed surface of the W plug and on sidewalls of the feature, and a conductive material substantially filling the feature. The interruption layer includes molybdenum (Mo).

Embodiments of the present disclosure provide a method of filling a feature in a semiconductor structure. The method generally includes selectively forming an interruption layer on an exposed surface of a conductive layer within the feature, the feature being formed in a dielectric layer formed over the conductive layer. The interruption layer includes molybdenum (Mo). The method also generally includes forming a liner layer on sidewalls of the feature and the interruption layer, and substantially filling the feature with a conductive material. The liner layer includes Mo or tungsten (W).

Embodiments provided herein generally include an interconnect formed in a substrate. The interconnect generally includes a dielectric layer with a tungsten (W) plug formed therein, a feature formed in the dielectric layer and over the W plug, an interruption layer formed on an exposed surface of the W plug, a liner layer formed on sidewalls of the feature and the interruption layer, and a conductive material substantially filling the feature. The interruption layer includes molybdenum (Mo) and the liner layer includes Mo or W.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a processing system that may be utilized to perform a deposition process according to one embodiment.

FIG. 2 is a flow diagram depicting a method of filling a feature in a semiconductor structure using a liner layer and an interruption layer, according to one or more of the embodiments described herein.

FIGS. 3A, 3B, 3C, and 3D illustrate schematic side cross-sectional views of a portion of a semiconductor structure during formation, according to one or more of the embodiments described herein.

FIG. 4 is a flow diagram depicting a method of filling a feature in a semiconductor structure using an interruption layer, according to one or more of the embodiments described herein.

FIGS. 5A, 5B, and 5C illustrate schematic side cross-sectional views of a portion of a semiconductor structure during formation, according to one or more of the embodiments described herein.

FIG. 6 is a flow diagram depicting a method of filling a feature in a semiconductor structure using a liner layer and a selective interruption layer, according to one or more of the embodiments described herein.

FIGS. 7A, 7B, 7C, and 7D illustrate schematic side cross-sectional views of a portion of a semiconductor structure during formation, according to one or more of the embodiments described herein.

FIG. 8A illustrates a graph of the roughness and grain size of a semiconductor device without an interruption layer, according to one or more of the embodiments described herein.

FIG. 8B illustrates a graph of the roughness and grain size of a semiconductor device with an interruption layer, according to one or more of the embodiments described herein.

FIG. 9 illustrates a graph of the resistivity and thickness of an interconnect structure in a semiconductor device, according to one or more of the embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments of the present disclosure generally relate to a semiconductor device that includes low resistance contacts and improved methods of forming the same. In some embodiments, the semiconductor device includes an interruption layer including molybdenum (Mo) formed in a feature (e.g., vias and/or trenches) of the semiconductor device. In some embodiments, the interruption layer may be formed on the feature and a conductive layer within the feature, formed on a liner layer which is formed on a feature and a conductive layer within the feature, or selectively formed only on a conductive layer within the feature.

The use of an interruption layer formed in accordance with embodiments and techniques of the present disclosure may reduce the resistance of the conductive features formed in semiconductor devices and enable a higher throughput process during the filling of the features.

### Processing System Example

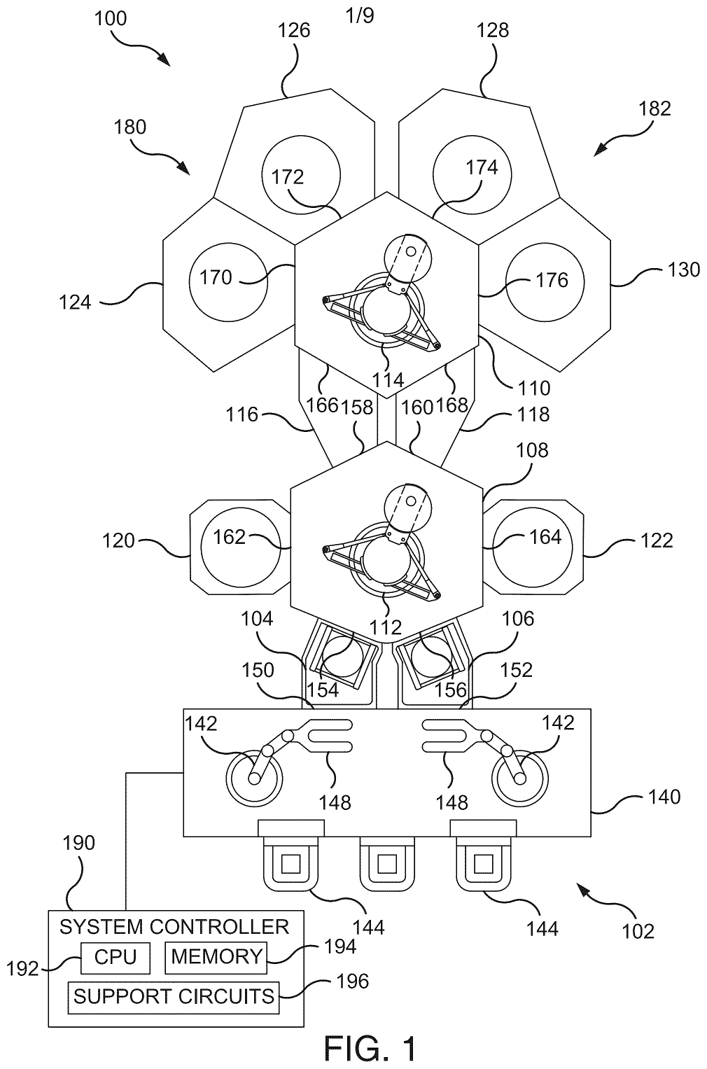

FIG. 1 illustrates a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Volta™ chemical vapor deposition or atomic level deposition (CVD/ALD) chamber, or Encore™ physical vapor deposition (PVD) chambers available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

### Semiconductor Structure Example

Contacts (e.g., interconnect structures) that have a low resistance are desirable in semiconductor devices. In some cases, a deposition process (e.g., a chemical vapor deposition (CVD) process) may be used to fill a feature (which may include vias and/or trenches) formed in a dielectric layer of a semiconductor device with a conductive material (e.g., tungsten (W)). Before filling the feature with the conductive material, a liner layer including W may be formed on the sidewalls of the feature and an exposed surface of a conductive layer within the feature. It is usually desirable that the conductive material have a low resistivity to allow electrical charge to flow easily without blocking due to rectification or excess power dissipation due to voltage thresholds. In addition, it is preferable to fill the features of a semiconductor device using a high throughout process to avoid negative impacts to tool productivity.

Embodiments of the present disclosure generally relate to a semiconductor device that include contacts that have a low resistance and improved methods of forming the same.

### Semiconductor Structure and Formation Sequence One

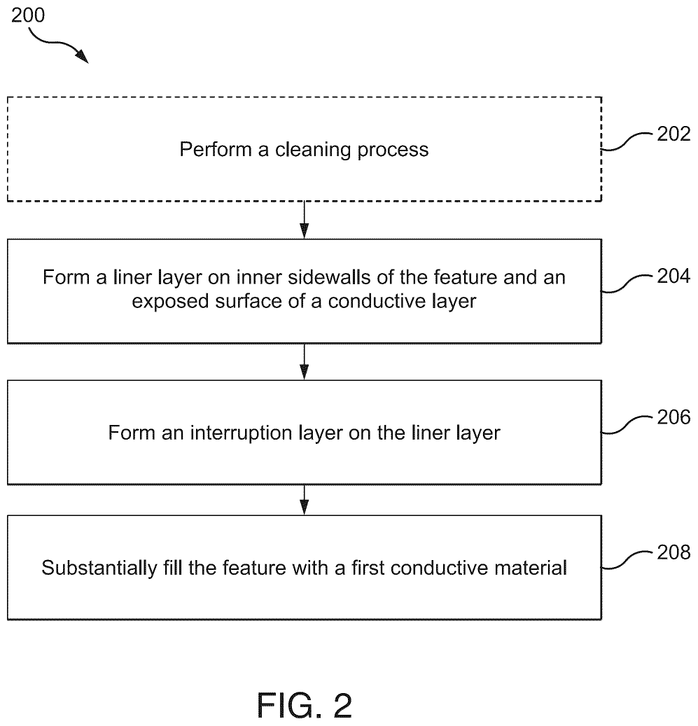

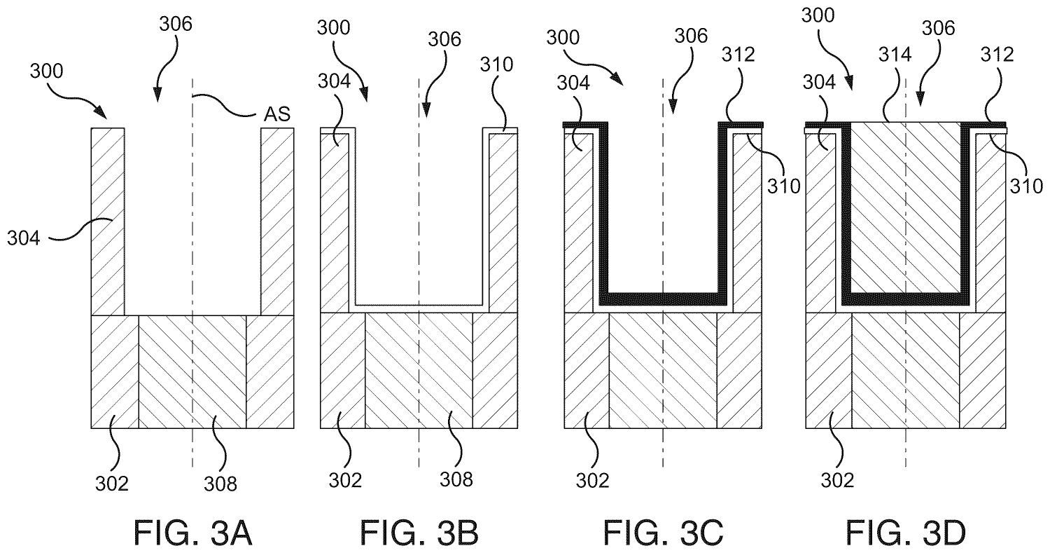

FIG. 2 is a flow diagram depicting a method 200 of filling a feature 306 in a semiconductor structure (such as an interconnect structure 300 formed on a substrate) using a liner layer 310 and an interruption layer 312, according to one or more of the embodiments described herein. FIGS. 3A, 3B, 3C, and 3D illustrate schematic side cross-sectional views of a portion of an interconnect structure 300 of a semiconductor structure during one or more of the activities illustrated in FIG. 2, according to one or more of the embodiments described herein. Therefore, FIG. 2 and FIGS. 3A, 3B, 3C, and 3D are herein described together for clarity. It is assumed that the interconnect structure 300 of the semiconductor device includes a dielectric layer (which includes a contact level dielectric layer 302 and a middle-end-of-line (MEOL) level dielectric layer 304) previously formed on a substrate (not shown), a feature 306, and a conductive layer 308, as illustrated in FIG. 3A. Within the feature 306, a surface of the conductive layer 308 is exposed, as shown. The feature 306 may include a via, a trench, or an interconnect, or any combination of a via, trench, and interconnect. The interconnect structure 300 of the semiconductor device may be symmetrical across the axis of symmetry (AS).

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The method 200 may optionally include, at activity 202, performing a cleaning process before forming a liner layer 310. The cleaning process includes a hydrogen (H) based reduction pre-clean, an argon and inert-gas based sputter pre-clean, or a combination of both the hydrogen based reduction pre-clean and the argon and inert-gas based sputter pre-clean. In one or more embodiments, the cleaning process may include generating a plasma that comprises a carrier gas. The plasma/carrier gas may then be provided to the surface of the semiconductor substrate. In one or more embodiments, the carrier gas may comprise a noble gas, such as argon, neon, and helium, and combinations thereof. In one example, the processing chamber 322 may be a SiCoNi™ pre-clean chamber available from Applied Materials of Santa Clara, Calif.

The method 200 may generally include, at activity 204, forming a liner layer 310 on sidewalls of the feature 306 and an exposed surface of a conductive layer 308 within the feature 306, as illustrated in FIG. 3B. The feature 306 is formed in a dielectric layer 302, 304 formed over the conductive layer 308. The liner layer 310 includes a conductive material that can include at least one of molybdenum (Mo) or tungsten (W). The conductive layer 308 may include W. In some embodiments, forming the liner layer 310 includes depositing the liner layer 310 by a physical vapor deposition (PVD) process, chemical vapor deposition (CVD) process or an atomic layer deposition (ALD) process. The PVD or ALD process may be performed in a processing chamber, such as the processing chamber 124, 126, 128, or 130 shown in FIG. 1. In some embodiments, the conductive layer 308 may be implemented as a W plug formed within the feature 306.

In some embodiments, forming the liner layer 310 includes a CVD or ALD process that includes a process that includes maintaining the process region of a process chamber at a pressure of between 0.1 mTorr to 500 Torr, a substrate temperature of room temperature (e.g., 20 degrees Celsius (° C.)) to 600° C., for a minimum period of time of 1 second, using precursor including at least one of MoCl₅, molybdenum oxytetrachloride (MoOCl₄), or MoF₆ and a carrier gas (e.g., inert gas) in combination with the presence of hydrogren (H₂) gas in order to deposit molybdenum atoms, in either a discontinuous layer or a continuous layer. In some embodiments, forming the liner layer 310 includes using process parameters that include maintaining the process region of a process chamber at a pressure of between 0.1 mTorr to 500 Torr, a temperature of 20° C. to 600° C., for a minimum period of time of 1 seconds, using precursor including at least one of tungsten (VI) chloride (WCl₆) or tungsten hexafluoride (WF₆) in the presence of H₂ gas in order to deposit a discontinuous or continuous layer of W. In some embodiments, the liner layer 310 may have a thickness that is less than 50% of the width of the feature 306.

The dielectric layer 302, 304 includes a contact level dielectric layer 302 and a MEOL level dielectric layer 304. The contact level dielectric layer 302 and the MEOL dielectric layer 304 may be formed of the same material, or of different materials. In some embodiments, the dielectric layer 302, 304 includes low k dielectric (SiOCH), silicon dioxide (SiO₂), silicon nitride (Si₃N₄), silicon carbide (SIC), aluminum oxide (Al₂O₃), or aluminum nitride (AlN).

The method 200 may generally include, at activity 206, forming an interruption layer 312 on the liner layer 310, as illustrated in FIG. 3C. The interruption layer 312 includes Mo. In some embodiments, forming the interruption layer includes exposing the liner layer 310 to a precursor including at least one of molybdenum (V) chloride (MoCl₅), molybdenum oxytetrachloride (MoOCl₄), molybdenum hexafluoride (MoF₆), or another molybdenum carbonyl compound. In some embodiments, forming the interruption layer 312 includes depositing the interruption layer 312 by a CVD process or an ALD process. The CVD or ALD process may be performed in a processing chamber, such as the processing chamber 124, 126, 128, or 130 shown in FIG. 1. The ALD process may be a thermal only ALD process (which generally uses a temperature of 425 to 450 degrees celsius (C)), or a plasma ALD process (which generally uses a temperature of 350 degrees C. or below). In some embodiments, the interruption layer 312 has a thickness less than 50 angstroms (Å), such as between 3 Å and 50 Å, or between 3 Å and 40 Å, or even or between 3 Å and 25 Å. In some embodiments, forming the interruption layer 312 includes using a CVD process that includes the process parameters including a pressure of 1 mTorr to 500 Torr, a substrate temperature of 100° C. to 600° C., a minimum period of time that will allow for Mo deposition, using precursor including at least one of MoCl₅, MoOCl₄, or MoF₆ and a carrier gas (e.g., inert gas) to react with H₂.

The method 200 may generally include, at activity 208, substantially filling the feature 306 with a conductive material 314, as illustrated in FIG. 3D. In some embodiments, the activity 208 may be performed in part by using an ALD or CVD deposition process that utilizes a metal containing precursor, such as a fluorine containing precursor or a fluorine free tungsten precursor. In one or more embodiments, the introduced precursor may comprise or consist essentially of a fluorine-free metal halide. Examples of tungsten halides include, but are not limited to, tungsten pentachloride (WCl₅) and tungsten hexachloride (WCl₆). In one or more embodiments, the fluorine-free tungsten precursor comprises or consists essentially of a tungsten oxyhalide precursor. Examples of a tungsten oxyhalide include, but are not limited to, tungsten oxytetrachloride (WOCl₄) and tungsten dichloride dioxide (WO₂Cl₂). In one or more embodiments, the fluorine-free tungsten precursor is also a chlorine-free tungsten precursor (CFW). Examples of a fluorine-free and chloride-free tungsten precursor includes, but is not limited to, tungsten pentabromide (WBr₅) and tungsten hexabromide (WBr₆). In one or more embodiments, the second metal-containing precursor may comprise fluorine-free metal organic, such as tris (3-hexyne) tungsten carbonyl (W(CO)(CH₃CH₂C≡CCH₂CH₃)₃).

In some embodiments, substantially filling the feature 306 with the conductive material 314 includes exposing the interruption layer 312 to a precursor including hydrogen (H₂) and at least one of tungsten (VI) hexafluoride (WF₆) or tungsten (V) chloride (WCl₅). In some embodiments, substantially filling the feature 306 with the conductive material 314 includes depositing the conductive material 314 by a CVD process. The CVD process may be performed in a processing chamber, such as the processing chamber 124, 126, 128, or 130 shown in FIG. 1. In some embodiments, the conductive material comprises tungsten (W). In one example, forming the interruption layer 312 includes using a CVD process that includes the process parameters including a pressure of 1 mTorr to 500 Torr, a substrate temperature of 100° C. to 600° C., a period of time required to fill the feature, using precursor including at least one of WF₆ or WCl₆, and a carrier gas (e.g., inert gas) in the presence of H₂.

In some embodiments, the method 200 may further include forming another liner layer (not shown) on the interruption layer 312 after forming the interruption layer 312. The other liner layer includes Mo or W. For example, when the liner layer 310 includes Mo, the other liner layer may include W, or vice versa.

### First Additional Semiconductor Structure and Formation Sequence

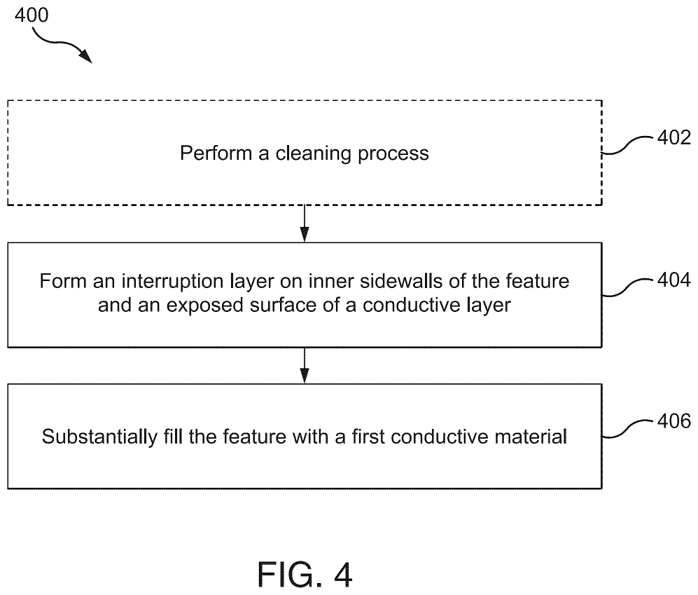

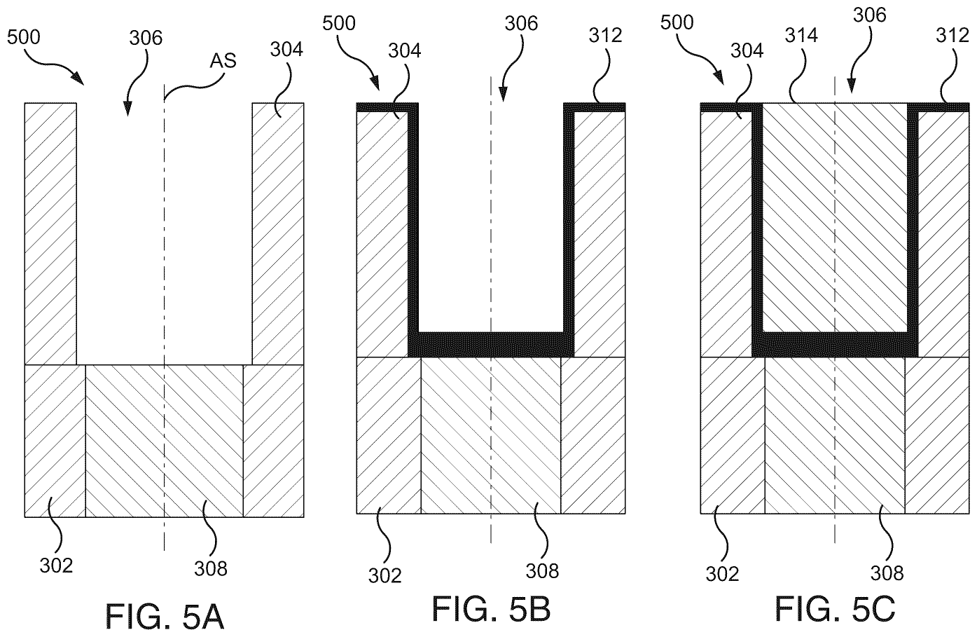

FIG. 4 is a flow diagram depicting a method 400 of filling a feature 306 in a semiconductor structure (such as an interconnect structure 500 formed on a substrate) using an interruption layer 312, according to one or more of the embodiments described herein. FIGS. 5A, 5B, and 5C illustrate schematic side cross-sectional views of a portion of an interconnect structure 500 of a semiconductor structure during one or more of the activities illustrated in FIG. 4, according to one or more of the embodiments described herein. Therefore, FIG. 4 and FIGS. 5A, 5B, and 5C are herein described together for clarity. It is assumed that the interconnect structure 500 of the semiconductor device includes a dielectric layer (including a contact level dielectric layer 302 and a middle-end-of-line (MEOL) level dielectric layer 304) previously formed on a substrate (not shown), a feature 306, and a conductive layer 308, as illustrated in FIG. 5A. Within the feature 306, a surface of the conductive layer 308 is exposed, as shown. The feature 306 may include a via, a trench, or an interconnect, or any combination of a via, trench, and interconnect. The interconnect structure 500 of the semiconductor device may be symmetrical across the AS.

The method 400 may optionally include, at activity 402, performing a cleaning process before forming an interruption layer 312. The cleaning process may be similar to the cleaning process described above with respect to method 200, and includes a hydrogen based reduction pre-clean, an argon and inert-gas based sputter pre-clean, or a combination of both the hydrogen based reduction pre-clean and the argon and inert-gas based sputter pre-clean. In some embodiments, activity 402 is the same as or substantially similar to activity 202, which is described above.

The method 400 may generally include, at activity 404, forming an interruption layer 312 on sidewalls of the feature 306 and an exposed surface of a conductive layer 308 within the feature 306, as illustrated in FIG. 5B. The process of forming the interruption layer 312 may be similar to the process described above with respect to activity 206 of method 200. The feature 306 is formed in a dielectric layer 302, 304 formed over the conductive layer 308. In one example, the interruption layer 312 includes Mo. In some embodiments, forming the interruption layer 312 includes exposing the dielectric layer 302, 304 to a precursor including at least one of MoCl₅, MoOCl₄, MoF₆, or another molybdenum carbonyl compound. In some embodiments, forming the interruption layer 312 includes depositing the interruption layer 312 by a CVD process or an ALD process. The CVD or ALD process may be performed in a processing chamber, such as the processing chamber 124, 126, 128, or 130 shown in FIG. 1. The ALD process may be a thermal only ALD process (which generally uses a temperature of 425 to 450° C.), or a plasma ALD process (which generally uses a temperature of 350° C. or below).

In some embodiments, the interruption layer 312 has a thickness less than 50 angstroms (Å), such as between 3 Å and 50 Å, or between 3 Å and 40 Å, or even or between 3 Å and 25 Å. In some embodiments, forming the interruption layer 312 includes using process parameters that include maintaining the process region of a process chamber at a pressure of between 1 mTorr to 500 Torr, a substrate temperature of 100° C. to 600° C., using precursor including at least one of MoCl₅, MoOCl₄, or MoF₆ and a carrier gas (e.g., inert gas) to react with H₂. In some embodiments, activity 404 is the same as or substantially similar to activity 206, which is described above.

The method 400 may generally include, at activity 406, substantially filling the feature 306 with a conductive material 314, as illustrated in FIG. 5C. In some embodiments, substantially filling the feature 306 with the conductive material 314 includes exposing the interruption layer 312 to a precursor including hydrogen (H₂) and at least one of WF₆ or WCl₅. In some embodiments, substantially filling the feature 306 with the conductive material 314 includes depositing the conductive material 314 by a CVD process. In some embodiments, activity 406 is the same as or substantially similar to activity 208, which is described above.

### Second Additional Semiconductor Structure and Formation

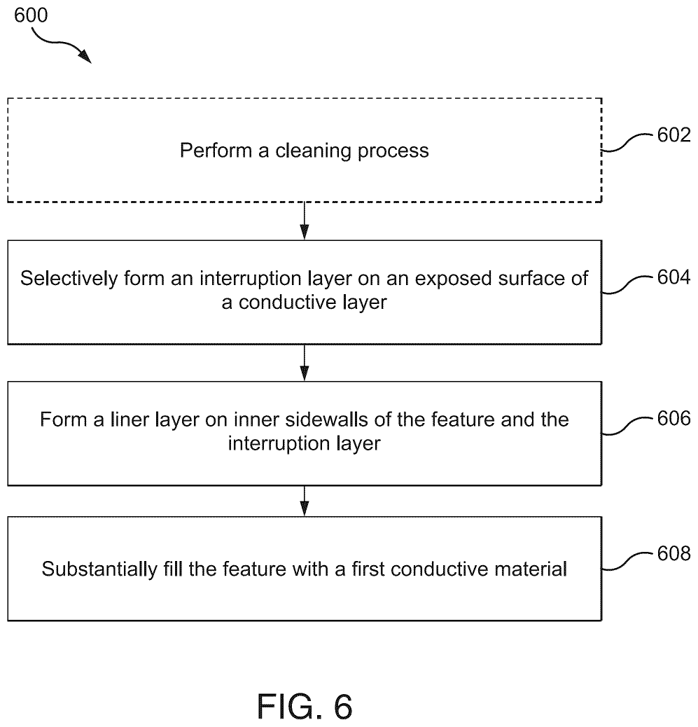

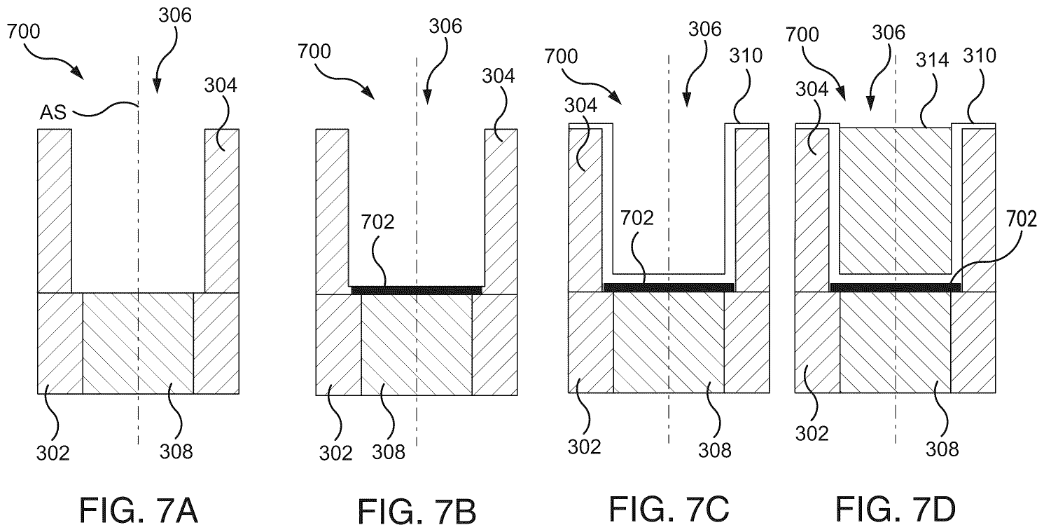

FIG. 6 is a flow diagram depicting a method 600 of filling a feature 306 in a semiconductor structure (such as an interconnect structure 700 formed on a substrate) using a liner layer 310 and a selective interruption layer 702, according to one or more of the embodiments described herein. FIGS. 7A, 7B, 7C, and 7D illustrate schematic side cross-sectional views of a portion of an interconnect structure 700 of a semiconductor structure during one or more of the activities illustrated in FIG. 6, according to one or more of the embodiments described herein. Therefore, FIG. 6 and FIGS. 7A, 7B, 7C, and 7D are herein described together for clarity. It is assumed that the interconnect structure 700 of the semiconductor device includes a dielectric layer (including a contact level dielectric layer 302 and a MEOL level dielectric layer 304) previously formed on a substrate (not shown) a feature 306, and a conductive layer 308, as illustrated in FIG. 7A. Within the feature 306, a surface of the conductive layer 308 is exposed, as shown. The feature 306 may include a via, a trench, or an interconnect, or any combination of a via, trench, and interconnect. The interconnect structure 700 of the semiconductor device may be symmetrical across the AS.

The method 600 may optionally include, at activity 602, performing a cleaning process before forming a selective interruption layer 702. The cleaning process may be similar to the cleaning process described above with respect to method 200 and method 400, and includes a hydrogen based reduction pre-clean, an argon and inert-gas based sputter pre-clean, or a combination of both the hydrogen based reduction pre-clean and the argon and inert-gas based sputter pre-clean. In some embodiments, activity 602 is the same as or substantially similar to activity 202, which is described above.

The method 600 may generally include, at activity 604, selectively forming a selective interruption layer 702 on an exposed surface of a conductive layer 308 within the feature, as illustrated in FIG. 7B. The feature is formed in a dielectric layer 302, 304 formed over the conductive layer 308. In one example, the selective interruption layer 702 includes Mo. In some embodiments, forming the interruption layer includes exposing the liner layer 310 to a precursor including MoCl₅. In some embodiments, forming the selective interruption layer 702 includes depositing the selective interruption layer 702 by a CVD process or an ALD process. The CVD or ALD process may be performed in a processing chamber, such as the processing chamber 124, 126, 128, or 130 shown in FIG. 1. The ALD process may be a thermal only ALD process (which generally uses a temperature of 425 to 450° C.), or a plasma ALD process (which generally uses a temperature of 350° C. or below). In some embodiments, the selective interruption layer 702 has a thickness less than 50 angstroms. In some embodiments, the selective interruption layer 702 is not formed on inner sidewalls of the feature 306, as illustrated.

In some embodiments, forming the interruption layer 312 includes using process parameters, the process parameters including a pressure of 1 mTorr to 500 Torr, a substrate temperature of 100° C. to 600° C., a minimum period of time that will allow for Mo deposition, using precursor including at least one of MoCl₅, MoOCl₄, or MoF₆ and a carrier gas (e.g., inert gas) to react with H₂. In some embodiments, activity 604 substantially similar to activity 206, which is described above.

The method 200 may generally include, at activity 606, forming a liner layer 310 on sidewalls of the feature 306 and the selective interruption layer 702, as illustrated in FIG. 7C. The liner layer 310 includes at least one of Mo or W. In some embodiments, forming the liner layer 310 includes depositing the liner layer 310 by a PVD process or an ALD process. The PVD or ALD process may be performed in a processing chamber, such as the processing chamber 124, 126, 128, or 130 shown in FIG. 1. In some embodiments, activity 606 is the same as or substantially similar to activity 204, which is described above.

The method 200 may generally include, at activity 608, substantially filling the feature 306 with a conductive material 314, as illustrated in FIG. 7D. In some embodiments, substantially filling the feature 306 with the conductive material 314 includes exposing the liner layer 310 to a precursor including at least one of WF₆ or WCl₅ and H₂. In some embodiments, substantially filling the feature 306 with the conductive material 314 includes depositing the conductive material 314 by a CVD process. The CVD process may be performed in a processing chamber, such as the processing chamber 124, 126, 128, or 130 shown in FIG. 1. In some embodiments, activity 608 is the same as or substantially similar to activity 208, which is described above.

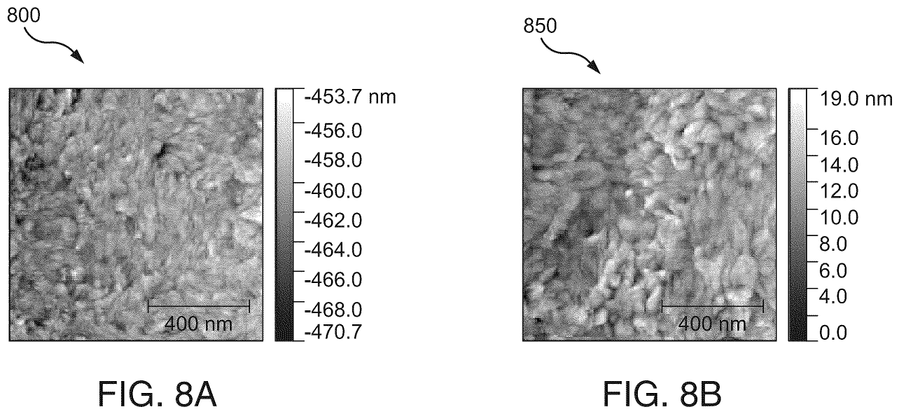

FIG. 8A illustrates a graph 800 of the roughness and grain size of a semiconductor device without an interruption layer (e.g., interruption layer 312 or selective interruption layer 702), according to one or more of the embodiments described herein. Graph 800 depicts an example interconnect of a semiconductor device manufactured without the interruption layer described herein, and results in a resistivity of about 16 micro-ohms per centimeter, and a root mean square (RMS) roughness of about 1.9 nanometers.

FIG. 8B illustrates a graph 850 of the roughness and grain size of a semiconductor device with an interruption layer (e.g., interruption layer 312 or selective interruption layer 702), according to one or more of the embodiments described herein. Graph 850 depicts an example interconnect (e.g., interconnect 300, 500, 700) of a semiconductor device manufactured with the interruption layer described herein, and results in a resistivity of about 12.9 micro-ohms per centimeter, and a RMS roughness of about 2.4 nanometers. The resistivity in graph 850 is about 21.5% lower than the resistivity of graph 800, while the RMS roughness of graph 850 is about 23.25% higher than the roughness of graph 800. As a result of the increased grain size found in the interconnect structures 300, 500, 700 of semiconductor devices with the interruption layer, the bulk resistivity of the interconnects decreases, which leads to less scattering of electric current that passes through the interconnect.

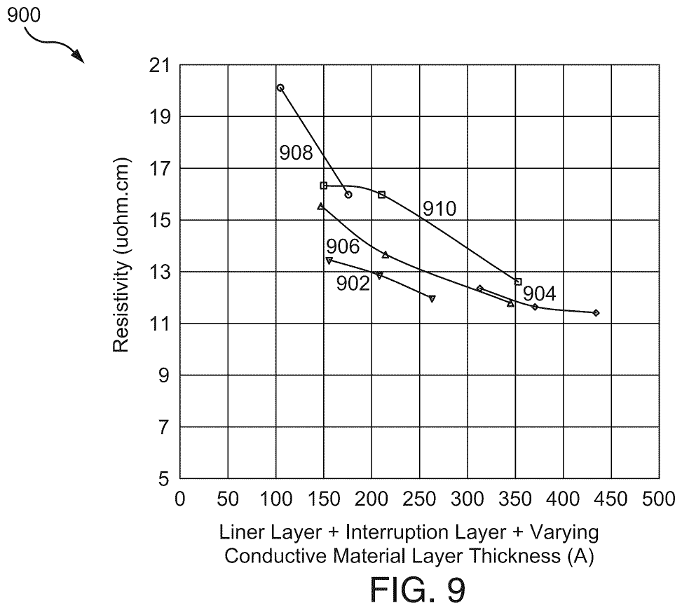

FIG. 9 illustrates a graph 900 of the resistivity and thickness of an interconnect structure stack (e.g., interconnect structure 300, 500, 700) that can be used in a semiconductor device, according to one or more of the embodiments described herein. The x-axis in the graph 900 refers to a interconnect structure stack that includes a combination of a PVD deposited tungsten liner layer (10 angstrom (A) thickness), differently deposited Mo containing interruption layers (e.g., interruption layer 312, selective interruption layer 702), and a conductive material layer (e.g., CVD deposited W layer), having a varying thickness as shown in the graph, formed thereon.

The curve 902 of graph 900 corresponds to an example of the resistivity of the interconnect structure 300 with a 30 Å thick W containing liner layer, an interruption layer that includes a 20 Å thick Mo, and a CVD deposited W layer, as a function of the CVD deposited W layer thickness. In the example shown in FIG. 2, the curve 902 illustrates the resistivity of a layer stack that includes an interruption layer that includes a 20 Å thick Mo formed by an ALD process that includes cyclically exposing substrate to a MoOCl₄ precursor at a pressure of between 0.1 Torr and 500 Torr, a substrate temperature of 450° C. to form a Mo layer that is 20 angstroms (Å) thick, as described above in activity 206.

The curve 904 of graph 900 corresponds to an example of the resistivity of the interconnect structure 300 with a 30 Å thick W containing liner layer, an interruption layer that includes a 20 Å thick Mo, and a CVD deposited W layer, as a function of the CVD deposited W layer thickness. In the example shown in FIG. 2, the curve 904 illustrates the resistivity of a layer stack that includes an interruption layer that includes a ALD process that includes exposing substrate to a MoOCl₄ precursor at a pressure of between 0.1 Torr and 500 Torr, and a substrate temperature of 450° C. and then depositing 20 Å of Mo formed by an PVD process.

The curve 906 of graph 900 corresponds to an example of the resistivity of the interconnect structure 300 with a 30 Å thick W containing liner layer, an interruption layer that includes a 40 Å thick Mo, and a CVD deposited W layer as a function of the CVD deposited W layer thickness. In the example shown in FIG. 2, the curve 906 illustrates the resistivity of a layer stack that includes an interruption layer that includes a 20 Å thick Mo formed by an CVD process that includes exposing substrate to a MoCl₅ precursor at a pressure of between 0.1 Torr and 500 Torr, a substrate temperature of 450° C. to form a Mo layer that is 20 Å thick and then depositing an additional 20 Å of Mo formed by an PVD process at a substrate temperature of 450° C.

The curve 910 of graph 900 corresponds to an example of the resistivity of a conventional interconnect structure with a 30 Å thick W containing liner layer and a CVD deposited W layer, as a function of the CVD deposited W layer thickness. The curve 910 of graph 900 thus corresponds to an example of the resistivity of an interconnect structure using only the liner layer that includes W without an interruption layer 312 as a function of the CVD deposited W layer thickness.

As illustrated in FIG. 2, the interconnect structures formed by the processes used to form curves 902, 904 and 906 contained the lowest resistivities of the formed stack structures. It has also been found that the processes used to form curves 904 and 906 can be used to maximize the resistance gain created by the formation of the interconnect structure stack, and have an improved substrate throughput, due to a reduction in the required deposition times.

It has been found that the techniques discussed herein for forming an interruption layer (e.g., interruption layer 312, selective interruption layer 702) in conductive features enables the formation of interconnect structures with a lower resistance compared to interconnect structures without an interruption layer. For example, forming interconnect structures with an interruption layer in accordance with the techniques discussed above (e.g., represented by example curves 902, 904, 906 in graph 900) greatly improves the resistivity of the interconnect structures when compared to interconnect structures without an interruption layer (e.g., represented by curves 908, 910).

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

While the foregoing is directed to embodiments of the present disclosure, other and further embodiments of the disclosure may be devised without departing from the basic scope thereof, and the scope thereof is determined by the claims that follow.

We claim:

1. A method of filling a feature in a semiconductor structure, the method comprising:
forming a liner layer on sidewalls of the feature and an exposed surface of a conductive layer within the feature, the feature being formed in a dielectric layer formed over the conductive layer, wherein the liner layer comprises molybdenum (Mo) or tungsten (W);
forming an interruption layer on the liner layer, wherein the interruption layer comprises Mo; and
substantially filling the feature with a conductive material.

2. The method of claim 1, wherein forming the liner layer comprises depositing the liner layer by a physical vapor deposition (PVD) process or an atomic layer deposition (ALD) process.

3. The method of claim 1, wherein forming the interruption layer comprises:
exposing the liner layer to a precursor comprising at least one of molybdenum (V) chloride (MoCl₅), molybdenum oxytetrachloride (MoOCl₄), molybdenum hexafluoride (MoF₆), or a molybdenum carbonyl compound; and
depositing the interruption layer by a chemical vapor deposition (CVD) process or an atomic layer deposition (ALD) process.

4. The method of claim 1, wherein substantially filling the feature with the conductive material comprises:
exposing the interruption layer to a precursor comprising at least one of tungsten hexafluoride (WF₆) or tungsten (V) chloride (WCl₅) and hydrogen (H₂); and
depositing the conductive material by a chemical vapor deposition (CVD) process.

5. The method of claim 1, wherein the conductive material comprises W.

6. The method of claim 1, wherein a thickness of the interruption layer is less than 50 angstroms.

7. The method of claim 1, wherein forming the interruption layer comprises:
delivering a first precursor comprising at least one of molybdenum (V) chloride (MoCl₅), molybdenum oxytetrachloride (MoOCl₄), or molybdenum hexafluoride (MoF₆) to a substrate heated to a first temperature of 100° C. to 600° C. and positioned in an environment maintained at a first pressure of 1 mTorr to 500 Torr; and
delivering a second precursor comprising at least one of MoCl₅, MoOCl₄, or MoF₆ to the substrate heated to a second temperature of 20° C. to 600° C. and positioned in the environment maintained at a second pressure of 0.1 mTorr to 500 Torr.

8. The method of claim 1, further comprising:
forming another liner layer on the liner layer before forming the interruption layer, wherein the other liner layer comprises molybdenum (Mo) or tungsten (W).

9. A method of filling a feature in a semiconductor structure, the method comprising:
forming an interruption layer on sidewalls of the feature and an exposed surface of a conductive layer within the feature, the feature being formed in a dielectric layer formed over the conductive layer, wherein the interruption layer comprises molybdenum (Mo); and
substantially filling the feature with a conductive material.

10. The method of claim 9, wherein forming the interruption layer comprises:
exposing the dielectric layer to a precursor comprising at least one of molybdenum (V) chloride (MoCl₅), molybdenum oxytetrachloride (MoOCl₄), molybdenum hexafluoride (MoF₆), or a molybdenum carbonyl compound; and
depositing the interruption layer by a chemical vapor deposition (CVD) process or an atomic layer deposition (ALD) process.

11. The method of claim 9, wherein substantially filling the feature with the conductive material comprises:
exposing the interruption layer to a precursor comprising at least one of tungsten hexafluoride (WF₆) or tungsten (V) chloride (WCl₅) and hydrogren (H₂); and
depositing the conductive material by a chemical vapor deposition (CVD) process.

12. The method of claim 9, wherein the conductive material comprises tungsten (W).

13. The method of claim 9, wherein a thickness of the interruption layer is less than 50 angstroms.

14. The method of claim 9, wherein forming the interruption layer comprises:
delivering a first precursor comprising at least one of molybdenum (V) chloride (MoCl₅), molybdenum oxytetrachloride (MoOCl₄), or molybdenum hexafluoride (MoF₆) to a substrate heated to a temperature of 100° C. to 600° C. and positioned in an environment maintained at a pressure of 1 mTorr to 500 Torr.

15. A method of filling a feature in a semiconductor structure, the method comprising:
selectively forming an interruption layer on an exposed surface of a conductive layer within the feature, the feature being formed in a dielectric layer formed over the conductive layer, wherein the interruption layer comprises molybdenum (Mo);
forming a liner layer on sidewalls of the feature and the interruption layer, wherein the liner layer comprises Mo or tungsten (W); and
substantially filling the feature with a conductive material.

16. The method of claim 15, wherein the interruption layer is not formed on sidewalls of the feature.

17. The method of claim 15, wherein forming the interruption layer comprises exposing the liner layer to a precursor comprising molybdenum (V) chloride (MoCl₅).

18. The method of claim 15, wherein forming the interruption layer comprises:
depositing the interruption layer by a chemical vapor deposition (CVD) process or a first atomic layer deposition (ALD) process; and
delivering a first precursor comprising at least one of molybdenum (V) chloride (MoCl₅), molybdenum oxytetrachloride (MoOCl₄), or molybdenum hexafluoride (MoF₆) to a substrate heated to a first temperature of 100° C. to 600° C. and positioned in an environment maintained at a first pressure of 1 mTorr to 500 Torr.

19. The method of claim 18, wherein forming the liner layer comprises:
depositing the liner layer by a physical vapor deposition (PVD) process or a second ALD process; and
delivering a second precursor comprising at least one of MoCl₅, MoOCl₄, or MoF₆ to the substrate heated to a second temperature of 20° C. to 600° C. and positioned in the environment maintained at a second pressure of 0.1 mTorr to 500 Torr.

20. The method of claim 15, wherein substantially filling the feature with the conductive material comprises:
exposing the interruption layer to a precursor comprising at least one of tungsten hexafluoride (WF₆) or tungsten (V) chloride (WCl₅) and hydrogren (H₂); and
depositing the conductive material by a chemical vapor deposition (CVD) process.
